(19) United States
(12) Patent Application Publication
(10) Pub. No.: US 2025/0142965 A1
(43) Pub. Date: May 1, 2025

(54) WIRING BOARD AND DISPLAY DEVICE

(71) Applicant: Sharp Display Technology Corporation, Kameyama City (JP)

(72) Inventors: YUKI YAMADA, Kameyama City (JP); HIRONOBU SAWADA, Kameyama City (JP); Hiroto AKIYAMA, Kameyama City (JP)

(21) Appl. No.: 18/902,922

(22) Filed: Oct. 1, 2024

(30) Foreign Application Priority Data
Oct. 25, 2023 (JP) 2023-183076

(51) Int. Cl. H01L 27/12; G02F 1/1362; G02F 1/1368

(52) U.S. Cl. CPC H10D 86/60; G02F 1/136286; G02F 1/1368; H10D 86/443

(57) ABSTRACT

A wiring board includes first lines and second lines extending along a first direction, a first electrode connected to the second lines, a third line extending along a second direction crossing the first direction, and a signal supply connected to the first lines and not connected to the second lines and the third line. At least two first lines that are arranged at an interval in the second direction and overlap at least two second lines, respectively, via an insulating film, and are defined as second line overlapping first lines. The signal supply is configured to supply a first signal to one of the second line overlapping first lines and supply a second signal having an opposite polarity from a polarity of the first signal to another one of the second line overlapping first lines. The third line is connected to the at least two second lines.

### CROSS REFERENCE TO RELATED APPLICATION

This application claims priority from Japanese Patent Application No. 2023-183076 filed on Oct. 25, 2023. The entire contents of the priority application are incorporated herein by reference.

### TECHNICAL FIELD

The present technology described herein relates to a wiring board and a display device.

### BACKGROUND

A wiring board included in a display device has been known. One example of such a wiring board is an array substrate of an in-cell touch panel that is built in a display device. Such a built-in touch panel includes an array substrate including sub-pixels, gate lines and data lines that are disposed on the array substrate to cross each other and are insulated from each other, self-capacitive electrodes that are portions of a same layer and independent of each other, and touch control lines that connect the self-capacitive electrodes to the touch detection chip. The gate lines and the data lines cross each other to define the sub-pixels. Each of the sub-pixels has a long side and a short side and includes a pixel electrode. The touch control lines extend along the short-side direction of the sub-pixels. Such a built-in touch panel is designed with a new pixel structure and the position of each touch control line is optimized and an aperture ratio is increased and power consumption is reduced.

Such a built-in touch panel includes metal lines that are included in a same layer as the layer of the touch control line and are insulated from each other. The metal lines are electrically connected to the self-capacitive electrodes via the via holes. This lowers an electrical resistance of the self-capacitive electrodes having a high electrical resistance value. However, if the metal lines are not properly connected to the self-capacitive electrodes, the connection resistance of the self-capacitive electrodes and the metal lines increases. An electric field created by the data lines may adversely affect the switching components near the metal lines via the metal lines.

### SUMMARY

The technology described herein was made in view of the above circumstances. An object is to reduce adverse effect by an electric field created by a first line.

(1) A wiring board according to the technology described herein includes first lines extending along a first direction, second lines extending along the first direction, a first electrode connected to the second lines, a third line extending along a second direction that crosses the first direction, and a signal supply section that is connected to the first lines and is not connected to the second lines and the third line. The second lines include at least two second lines that are arranged at an interval in the second direction. The first lines include at least two first lines that are arranged at an interval in the second direction and overlap the at least two second lines, respectively, via an insulating film, and are defined as second line overlapping first lines. The signal supply section is configured to supply a first signal to one of the second line overlapping first lines and supply a second signal having an opposite polarity from a polarity of the first signal to another one of the second line overlapping first lines. The third line is connected to the at least two second lines.

(2) The wiring board may further include, in addition to (1), fourth lines that extend along the first direction and are connected to the first electrode, and a fifth line extending along the second direction. The fourth lines may include at least two fourth lines that are arranged at an interval with respect to the second direction. The first lines may include another at least two first lines that are arranged at an interval with respect to the second direction and overlap the at least two fourth lines, respectively, via the insulating film and may be defined as fourth line overlapping first lines. The signal supply section may be configured to supply a third signal to the at least two fourth lines, supply a fourth signal to one of the fourth line overlapping first lines, and supply a fifth signal to another one of the fourth line overlapping first lines, the fifth signal has an opposite polarity from a polarity of the fourth signal. The fifth line may be connected to the at least two fourth lines.

(3) The wiring board may further include, in addition to (1) or (2)o claim 1, second electrodes, and switching components connected to the first lines and the second electrodes, respectively. The second lines may be disposed such that portions of the second lines overlap at least portions of the switching components, respectively, via the insulating film.

(4) In the wiring board, in addition to any one of (1) to (3), the third line may include at least two third lines that are arranged at an interval with respect to the first direction and the at least two third lines may be connected to the at least two second lines.

(5) A display device according to the technology described herein includes the wiring board according to any one of (1) to (4) and an opposed substrate opposed to the wiring board with a gap.

According to the technology described herein, adverse effect by an electric field created by a first line is reduced.

### BRIEF DESCRIPTION OF THE DRAWINGS

FIG. 1 is a plan view illustrating a liquid crystal panel, a driver, and a flexible substrate included in a liquid crystal display device according to a first embodiment.

FIG. 2 is a cross-sectional view illustrating the liquid crystal panel, the driver, and the flexible substrate included in the liquid crystal panel according to the first embodiment.

FIG. 3 is a circuit diagram illustrating an electrical configuration of an array substrate included in the liquid crystal panel according to the first embodiment.

FIG. 4 is a cross-sectional view illustrating a cross-sectional configuration of a portion of the liquid crystal panel according to the first embodiment including source lines, touch lines, first connection lines, and pixel electrodes.

FIG. 5 is a cross-sectional view illustrating a cross-sectional configuration of a portion of the array substrate according to the first embodiment including a TFT and the touch line.

FIG. 6 is a plan view schematically illustrating a touch electrode, the gate lines, the source lines, the touch lines, and the connection lines, and short-circuit lines according to the first embodiment.

FIG. 7 is a cross-sectional view illustrating a cross-sectional configuration of a portion of the array substrate according to the first embodiment including the TFT and a first connection line.

FIG. 8 is a cross-sectional view illustrating a cross-sectional configuration of a portion of the array substrate according to the first embodiment including a first short-circuit line and the gate line.

FIG. 9 is a plan view schematically illustrating the touch electrode, the gate lines, the source lines, the touch lines, and the connection lines, and short-circuit lines according to a second embodiment.

FIG. 10 is a plan view schematically illustrating the touch electrode, the gate lines, the source lines, the touch lines, and the connection lines, and short-circuit lines according to a third embodiment.

FIG. 11 is a plan view schematically illustrating the touch electrode, the gate lines, the source lines, the touch lines, and the connection lines, and short-circuit lines according to a fourth embodiment.

FIG. 12 is a plan view schematically illustrating the touch electrode, the gate lines, the source lines, the touch lines, and the connection lines, and short-circuit lines according to a fifth embodiment.

### DETAILED DESCRIPTION

### First Embodiment

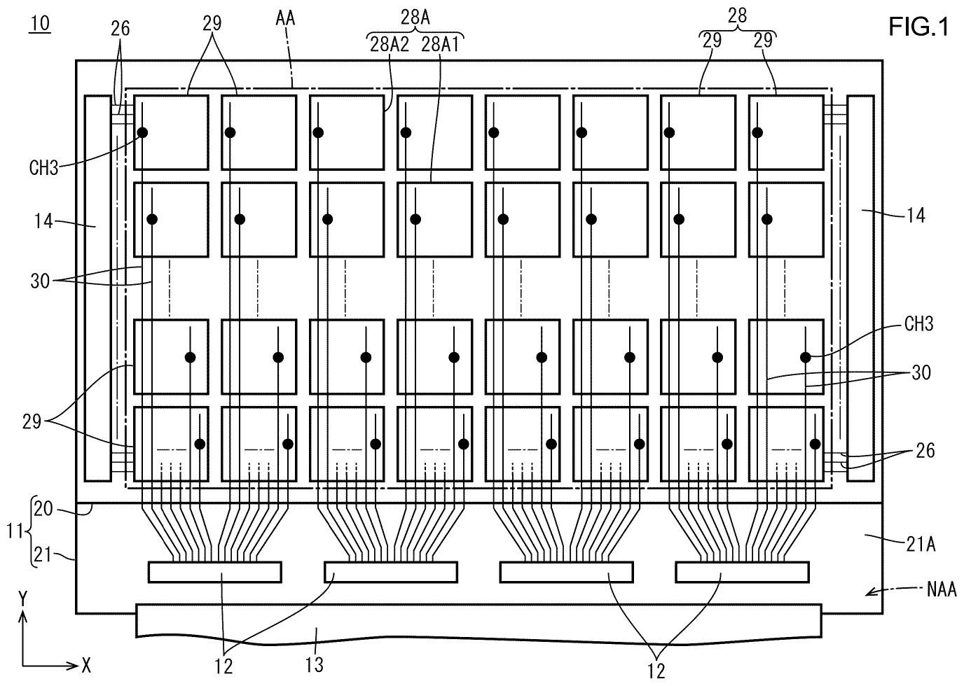

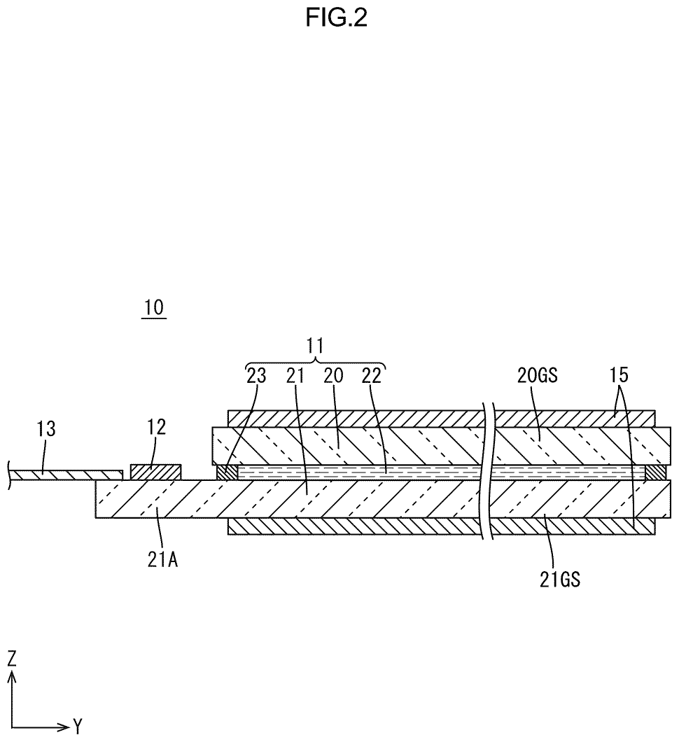

A first embodiment will be described with reference to FIGS. 1 to 8. In this embodiment section, a liquid crystal display device 10 with an image display function and a touch panel function (a position input function) will be described. X-axes, Y-axes, and Z-axes may be present in the drawings. The axes in each drawing correspond to the respective axes in other drawings. An upper side and a lower side in FIGS. 2, 4, 5, 7, and 8 correspond to a front side and a back side of the liquid crystal display device 10, respectively.

As illustrated in FIG. 1, the liquid crystal display device 10 at least includes a liquid crystal panel 11 (a display device, a display panel) that has a laterally long rectangular plan view shape and displays an image and a backlight unit (a lighting device) that is an external light source and supplies light to the liquid crystal panel 11 for displaying. The backlight unit is disposed behind (on a back surface side of) the liquid crystal panel 11. The backlight unit includes light sources configured to emit white light (e.g., LEDs) and optical members for converting the light from the light sources into planar light by applying optical effects to the light from the light sources. A middle section of a screen of the liquid crystal panel 11 is configured as a display area AA in which images are displayed. An outer section in a frame shape surrounding the display area AA in the screen of the liquid crystal panel 11 is configured as a non-display area NAA in which the images are not displayed.

As illustrated in FIG. 1, circuits 14 (a surrounding circuit, a gate circuit) are disposed in the non-display area NAA of the liquid crystal panel 11. A pair of circuits 14 are disposed to sandwich the display area AA with respect to the X-axis direction. The circuit 14 disposed in a belt shape area extending in the Y-axis direction. The circuits 14 are for supplying scan signals to gate lines 26, which will be described later, and are monolithically fabricated on an array substrate 21, which will be described later. The circuit 14 is a gate driver monolithic (GDM) circuit. The circuit 14 includes a shift resister circuit that is configured to output the scan signal at a predetermined timing and a buffer circuit that is configured to amplify the scan signal.

The liquid crystal panel 11 will be described in detail with reference to FIGS. 1 and 2. As illustrated in FIGS. 1 and 2, the liquid crystal panel 11 includes a pair of substrates 20, 21 that are bonded to each other. One of the substrates 20, 21 on the front side (a front surface side) is an opposed substrate 20 (a CF substrate) and another one on the back side (a back surface side) is an array substrate 21 (a wiring board). The opposed substrate 20 and the array substrate 21 include glass substrates 20GS, 21GS (a substrate) and various kinds of films are formed in layers on an inner surface side the glass substrates 20GS, 21GS. A liquid crystal layer 22 (a medium layer) is disposed between the substrates 20 and 21. The liquid crystal layer 22 includes liquid crystal molecules having optical characteristics that vary according to application of electric field. A sealing portion 23 is disposed between the outer peripheral portions of the substrates 20, 21 for sealing the liquid crystal layer 22. The sealing portion 23 is formed in a frame shape (an endless loop shape) and surrounds the liquid crystal layer 22. Polarizing plates 15 are attached to outer surfaces of the substrates 20 and 21.

As illustrated in FIGS. 1 and 2, the opposed substrate 20 has a short-side dimension that is smaller than a short-side dimension of the array substrate 21. The opposed substrate 20 is bonded to the array substrate 21 such that one of the long sides of the opposed substrate 20 is aligned with a corresponding one of the long sides of the array substrate 21. Therefore, a long side edge section including another one of the long sides of the array substrate 21 projects from another one of the long sides of the opposed substrate 20 and a projecting long side edge section is an uncovered section 21A. An entire area of the uncovered section 21A is the non-display area NAA and drivers 12 (a signal supply section) that are components for supplying various signals related to a display function and a touch panel function and a flexible substrate 13 are mounted on the uncovered section 21A.

The drivers 12 illustrated in FIGS. 1 and 2 are LSI chips including driver circuits therein. The drivers 12 are mounted on the uncovered section 21A of the array substrate 21 through the chip-on-glass (COG) technology. The driver 12 processes the various kinds of signals transmitted from the flexible substrate 13. The drivers 12 are components for supplying various kinds of signals (such as image signals and touch signals) to the lines (specifically, source lines 27 and touch lines 30, which will be described later) in the display area AA. The flexible substrate 13 includes a synthetic resin substrate (e.g., polyimide-based resin substrate) having insulating property and flexibility and multiple traces formed on the substrate. As illustrated in FIGS. 1 and 2, a first end of the flexible substrate 13 is connected to the uncovered section 21A of the array substrate 21 and a second end of the flexible substrate 13 is connected to an external circuit board (a control board). The flexible substrate 13 is connected to an end of the uncovered section 21A that is an opposite end from the display area AA with respect to the drivers 12 in the Y-axis direction.

The liquid crystal panel 11 according to this embodiment has a display function for displaying images and a touch panel function for detecting positions of input performed by a user based on the displayed images (input positions). The liquid crystal panel 11 includes an integrated touch panel pattern (with an in-cell technology) for exerting the touch panel function. The touch panel pattern uses so-called a projection type electrostatic capacitance method. A self-capacitance method is used for detection. As illustrated in FIG. 1, the touch panel pattern includes touch electrodes 29 (a first electrode, a position detection electrode) that are arranged in a matrix within the plate surface of the liquid crystal panel 11. The touch electrodes 29 are disposed in the display area AA of the liquid crystal panel 11. The display area AA of the liquid crystal panel 11 substantially corresponds to a touch area in which input positions are detectable (a position input area). The non-display area NAA substantially corresponds to a non-touch area in which input positions are not detectable (a non-position input area). When the user intends to input a position based on a displayed image that is displayed in the display area AA of the liquid crystal panel 11 and the user moves a finger (a position input body) that is an electrically conductive member closer to the surface of the liquid crystal panel 11 (a display surface), the finger and the touch electrode 29 form a capacitor. A capacitance measured at the touch electrode 29 close to the finger changes as the finger approaches the touch electrode 29 and is different from a capacitance at the touch electrodes 29 farther from the finger. Based on the difference in capacitance, the input position can be detected. The specific number of touch electrodes 29 can be altered from the one illustrated in FIG. 1. The touch electrode 29 has a substantially square plan view shape and one side dimension is about several millimeters. The plan view size of the touch electrode 29 is much larger than that of a pixel, which will be described later. The touch electrode 29 extends to overlap the pixels both in the X-axis direction and the Y-axis direction.

As illustrated in FIG. 1, touch lines 30 (fourth lines, position detection lines) on the liquid crystal panel 11 are selectively connected to the touch electrodes 29, respectively. The touch lines 30 extend substantially along the Y-axis direction. One ends of the touch lines 30 are connected to the driver 12 in the non-display area NAA and other ends are connected to the specific touch electrodes 29 among the touch electrodes 29 arranged in the Y-axis direction in the display area AA. The touch lines 30 are connected to a detection circuit. The detection circuit may be included in the driver 12 or provided outside the liquid crystal panel 11 and connected via the flexible substrate 13. A specific configuration of the touch lines 30 will be described later.

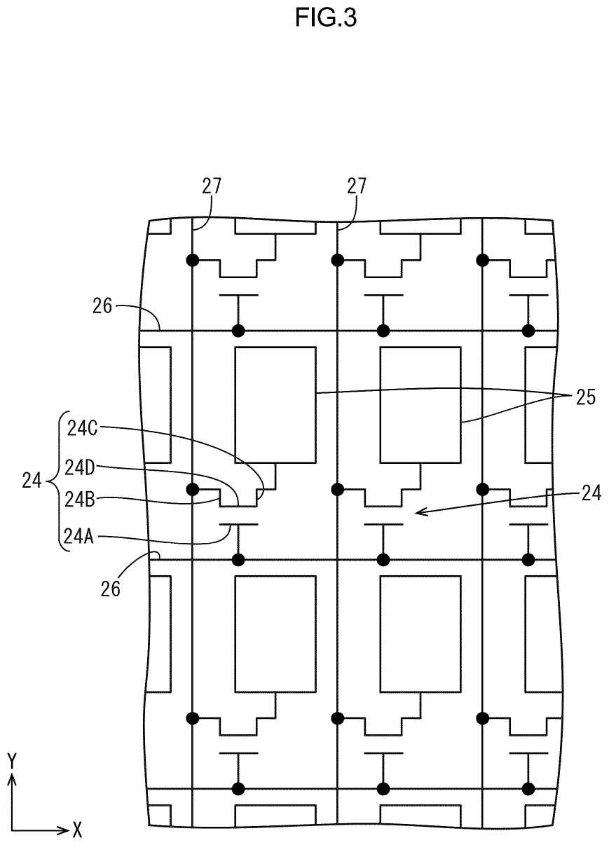

Next, a configuration of the array substrate 21 in the display area AA will be described with reference to FIG. 3. As illustrated in FIG. 3, thin film transistors (TFTs) 24 (switching components) and pixel electrodes 25 (second electrodes) are at least arranged in an area of an inner surface of the array substrate 21 in the display area AA. The TFTs 24 and the pixel electrodes 25 are arranged at intervals in a matrix (rows and columns) along the X-axis direction and the Y-axis direction. Gate lines 26 (sixth lines, scanning lines) and source lines 27 (first lines, image lines, signal lines) are routed perpendicular to each other (with crossing) to surround the TFTs 24 and the pixel electrodes 25. The gate lines 26 extend substantially straight in a direction substantially along the X-axis direction and are arranged at intervals with respect to the Y-axis direction. The source lines 27 extend in a direction substantially along the Y-axis direction (a first direction) and are arranged at intervals with respect to the X-axis direction (a second direction crossing the first direction) The TFT 24 includes a gate electrode 24A that is connected to the gate line 26, a source electrode 24B that is connected to the source line 27, a drain electrode 24C that is connected to the pixel electrode 25, and a semiconductor section 24D that is connected to the source electrode 24B and the drain electrode 24C. The TFTs 24 are driven based on scan signals supplied to the gate electrodes 24A through the gate lines 26. Through the driving of the TFT 24, a potential related to the image signal (a first signal, a second signal, a fourth signal, a fifth signal) that is supplied to the source electrode 24B through the source line 27 from the driver 12 is supplied to the drain electrode 24C via the semiconductor section 24D. As a result, the pixel electrode 25 is charged at the potential related to the pixel signal. The pixel electrode 25 is arranged in an area surrounded by the gate lines and the source lines 27 and has a substantially rectangular plan view shape. The pixel electrodes 25 include slits, which are not illustrated in FIG. 3.

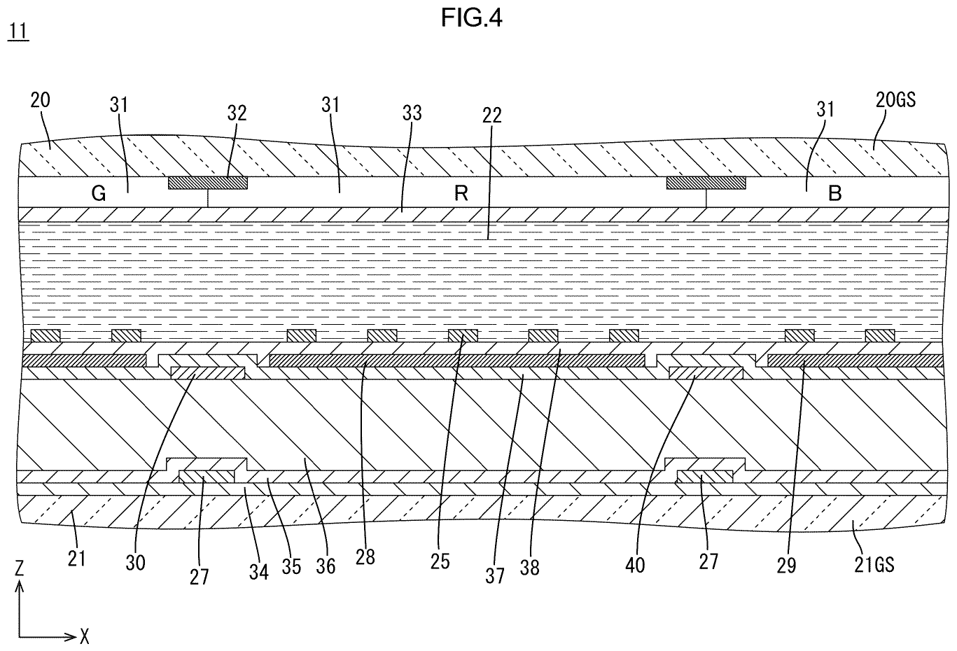

Next, a cross-sectional configuration of a middle section of the pixel electrode 25 of the liquid crystal panel 11 will be described with reference to FIG. 4. As illustrated in FIG. 4, color filters 31 that exhibit three different colors of blue (B), green (G), and red (R) are disposed in the display area AA on the inner surface side of the opposed substrate 20 of the liquid crystal panel 11. The color filters 31 that exhibit different colors are repeatedly arranged along the gate lines 26 (in the X-axis direction) and the color filters 31 that exhibit different colors extend along the source lines 27 (substantially the Y-axis direction). Namely, the color filters 31 that exhibit different colors are arranged in a stripe as a whole. The color filters 31 are arranged to overlap the pixel electrodes 25 of the array substrate 21, respectively, in a plan view. The color filter 31 and the corresponding pixel electrode 25 are configured as a pixel, which is a display unit. The color filters 31 that exhibit different colors are arranged such that a boundary therebetween (a color boundary) overlaps the source line 27. A light blocking portion 32 (an inter-pixel light blocking portion, a black matrix) is disposed on an inner surface side of the opposed substrate 20 and on a lower layer side of the color filters 31. The light blocking portion 32 is made of light blocking material having good light blocking properties. The light blocking portion 32 blocks light from the backlight unit. The light blocking portion 32 is formed in a grid pattern in a plan view in the display area AA to define each of the adjacent pixel electrodes 25 (pixels). The light blocking portion 32 is disposed to at least overlap the gate lines 26 and the source lines 27 on the array substrate 21 side. On an upper layer side (the liquid crystal layer 22 side) of the color filter 31, an overcoat film 33 is disposed in a solid manner on a substantially entire area of the opposed substrate 20 for planarization. Alignment films for orienting the liquid crystal molecules in the liquid crystal layer 22 are formed on innermost surfaces (in an uppermost layer) of the substrates 20 and 21 in contact with the liquid crystal layer 22.

As illustrated in FIG. 4, a common electrode 28 is formed to overlap all the pixel electrodes 25 on an inner surface side of the array substrate 21 in the display area AA. The common electrode 28 spreads over substantially an entire area of the display area AA. The common electrode 28 is disposed on a lower layer side of (closer to the glass substrate 21GS than) the pixel electrodes 25 via a third interlayer insulating film 38. The common electrode 28 is supplied with a common potential signal of a common potential (a reference potential). With the pixel electrode 25 being charged with a potential based on the image signal transmitted to the source line 27 according to the driving of the TFT, a potential difference occurs between the pixel electrode 25 and the common electrode 28. Then, a fringe electric field (an oblique electric field) is created between an opening edge of a slit of the pixel electrode 25 and the common electrode 28. The fringe electric field includes a component parallel to the plate surface of the array substrate 21 and a component normal to the plate surface of the array substrate 21. With the fringe electric field, orientations of the liquid crystal molecules included in the liquid crystal layer 22 can be controlled. Based on the orientations of the liquid crystal molecules, predefined display is performed. Namely, the liquid crystal panel 11 according to this embodiment operates in the fringe field switching (FFS) mode.

As illustrated in FIG. 1, the touch electrodes 29 are portions of the common electrode 28. The common electrode 28 includes dividing openings 28A (dividing slits) for separating the adjacent touch electrodes 29 from each other. The dividing openings 28A include first dividing openings 28A1 that cross the common electrode 28 in the X-axis direction for an entire length of the common electrode 28 and second dividing openings 28A2 that cross the common electrode 28 in the Y-axis direction for an entire length of the common electrode 28. The dividing openings 28A are formed in a grid in a plan view as a whole. The common electrode 28 is divided into the touch electrodes 29 with a grid pattern in a plan view by the dividing openings 28A and includes the touch electrodes 29 that are electrically independent from one another. The touch electrodes 29 that are arranged along the Y-axis direction are separated by the first dividing openings 28A1 and the touch electrodes 29 that are arranged along the X-axis direction are separated by the second dividing openings 28A2. The touch lines 30 that are connected to the touch electrodes 29 are supplied with common potential signals (a third signal) for the image display function and touch signals (the third signal, a position detection signal) for the touch function from the driver 12 at different timing. A period while the touch lines 30 are supplied with the common potential signals from the driver 12 is a display period and a period while the touch lines 30 are supplied with the touch signals from the driver 12 is a sensing period (a position detection period). The common potential signals are transmitted to all the touch lines 30 at the same timing (for the display period) and thus all the touch electrodes 29 are charged at the reference potential based on the common potential signals and function as the common electrode 28.

As illustrated in FIG. 4, the touch lines 30 are disposed to overlap the source lines 27, respectively, in a plan view. As illustrated in FIG. 1, the touch lines 30 cross the first dividing openings 28A1 that define each of the touch electrodes 29 that are adjacent to each other in the Y-axis direction.

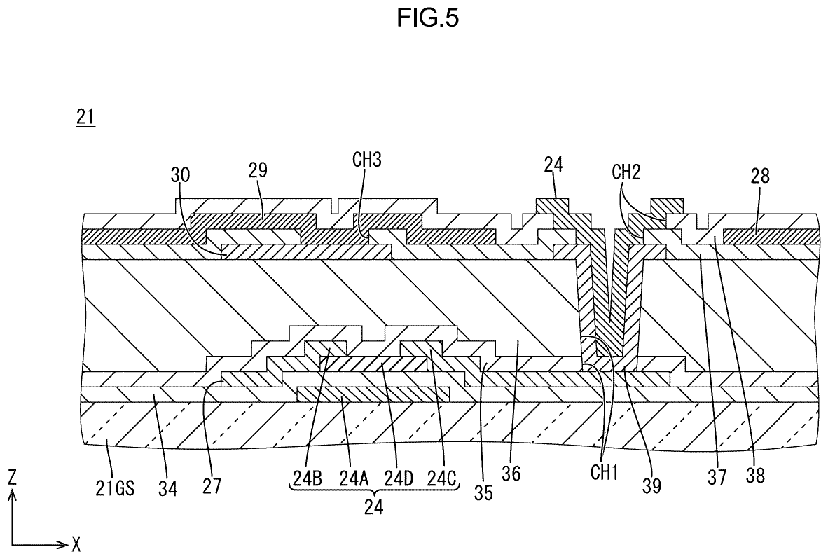

Films disposed on top of each other on the inner surface side of the array substrate 21 will be described with reference to FIG. 5. FIG. 5 illustrates a cross-sectional configuration of a portion of the array substrate 21 near the TFT 24 and the touch line 30. As illustrated in FIG. 5, on the glass substrate 21GS (a substrate) of the array substrate 21, a first metal film, a gate insulating film 34, a semiconductor film, a second metal film (a first conductive film), a first interlayer insulating film 35 (an insulating film), a planarization film 36 (an insulating film), a third metal film (a second conductive film), a second interlayer insulating film 37 (an insulating film), a first transparent electrode film, the third interlayer insulating film 38 (an insulating film), a second transparent electrode film, and an alignment film are disposed on top of each other in this sequence from a lower layer side (from the glass substrate 21GS side).

The first metal film, the second metal film, and the third metal film may be a single-layer film made of one kind of metal, a multilayer film made of a material containing different kinds of metals, or an alloy. Examples of the metals include copper, titanium, aluminum, molybdenum, and tungsten. With such a configuration, the first metal film, the second metal film, and the third metal film have electrically conductive properties and light blocking properties. The gate lines 26 and the gate electrodes 24A of the TFTs 24 are portions of the first metal film. The source lines 27, the source electrodes 24B and the drain electrodes 24C of the TFTs 24 are portions of the second metal film. The touch lines 30 are portions of the third metal film. The first transparent electrode film and the second transparent electrode film are made of a transparent electrode material (e.g., indium tin oxide (ITO) and indium zinc oxide (IZO)). The common electrode 28 (the touch electrodes 29) are portions of the first transparent electrode film. The pixel electrodes 25 are portions of the second transparent electrode film. The alignment films are configured as previously described.

The semiconductor film is made of an oxide semiconductor material and the semiconductor portions 24D of the TFTs 24 are portions of the semiconductor film. The semiconductor film may include at least one kind of metallic elements out of In, Ga, and Zn and may be an In—Ga—Zn—O semiconductor (for example, In—Ga—Zn oxide). The In—Ga—Zn—O semiconductor is ternary oxide of indium (In), gallium (Ga), and zinc (Zn). A ratio (composition ratio) of indium (In), gallium (Ga), and zinc (Zn) is not particularly limited and may be In:Ga:Zn=2:2:1, In:Ga:Zn=1:1:1, and In:Ga:Zn=1:1:2, for example. The In—Ga—Zn—O semiconductor used for the semiconductor film may be amorphous or may be crystalline. The semiconductor film may include other oxide semiconductor instead of the In—Ga—Zn—O semiconductor. For example, the semiconductor film may include an In—Sn—Zn—O semiconductor (for example, In₂O₃—SnO₂—ZnO; InSnZnO). The In—Sn—Zn—O semiconductor is ternary oxide of indium (In), tin (Sn), and zinc (Zn). The oxide semiconductor layer may include an In—W—Zn—O semiconductor, an In—W—Sn—Zn—O semiconductor that include tungsten (W), an In—Al—Zn—O semiconductor, an In—Al—Sn—Zn—O semiconductor, a Zn—O semiconductor, an In—Zn—O semiconductor, a Zn—Ti—O semiconductor, a Cd—Ge—O semiconductor, a Cd—Pb—O semiconductor, cadmium oxide (CdO), a Mg—Zn—O semiconductor, an In—Ga—Sn—O semiconductor, an In—Ga—O semiconductor, a Zr—In—Zn—O semiconductor, a Hf—In—Zn—O semiconductor, an Al—Ga—Zn—O semiconductor, a Ga—Zn—O semiconductor, and an In—Ga—Zn—Sn—O semiconductor. The resistance value of the oxide semiconductor material of the semiconductor film with no application of a voltage (off state) is higher than that of polysilicon semiconductor material. The oxide semiconductor material of the semiconductor film has electron mobility higher than that of amorphous silicon semiconductor material.

The gate insulating film 34, the first interlayer insulating film 35, the second interlayer insulating film 37, and the third interlayer insulating film 38 are made of an inorganic material such as silicon nitride (SiN_{X}) and silicon oxide (SiO₂). The thickness of each of the gate insulating film 34, the first interlayer insulating film 35, the second interlayer insulating film 37, and the third interlayer insulating film 38 is greater than a thickness of the first transparent electrode film and a thickness of the second transparent electrode film. The planarization film 36 is made of an organic material such as PMMA (acrylic resin) and is much thicker than the gate insulating film 34, the first interlayer insulating film 35, the second interlayer insulating film 37, and the third interlayer insulating film 38. The planarization film 36 planarizes the inner surface (a surface opposite the liquid crystal layer 22) of the array substrate 21. The gate insulating film 34 insulates the first metal film in the lower layer from the semiconductor film and the second metal film in the upper layer. For example, crossing portions of the gate lines 26, which are portions of the first metal film, and the source lines 27, which are portions of the second metal film, are insulated from each other by the gate insulating film 34. In the TFT 24, an overlapping portion of the gate electrode 24A, which is a portion of the first metal film, and the semiconductor section 24D, which is a portion of the semiconductor film, is insulated from each other by the gate insulating film 34. The first interlayer insulating film 35 and the planarization film 36 insulate the semiconductor film and the second metal film in the lower layer from the third metal film in the upper layer. For example, an overlapping portion of the source line 27, which is a portion of the second metal film, and the touch line 30, which is a portion of the third metal film, is insulated from each other by the first interlayer insulating film 35 and the planarization film 36. The second interlayer insulating film 37 insulates the third metal film in the lower layer from the first transparent electrode film in the upper layer. For example, an overlapping portion of the touch line 30, which is a portion of the third metal film, and the common electrode 28 (the touch electrode 29), which is a portion of the first transparent electrode film, is insulated by the second interlayer insulating film 37. The third interlayer insulating film 38 insulates the first transparent electrode film in the lower layer from the second transparent electrode film in the upper layer. For example, an overlapping portion of the common electrode 28 (the touch electrode 29), which is a portion of the first transparent electrode film, and the pixel electrode 25, which is a portion of the second transparent electrode film, is insulated by the third interlayer insulating film 38.

A configuration of the TFTs 24 will be described in detail. As illustrated in FIG. 5, in the TFTd 24, the gate electrodes 24A, which are portions of the first metal film, are disposed below the semiconductor sections 24D, which are portions of the semiconductor film, via the gate insulating film 34. Namely, the TFTs 24 are bottom-gate type transistors. The gate electrodes 24A are wide sections of the gate lines 26 that extend in the X-axis direction. The source electrode 24B and the drain electrode 24C, which are portions of the second metal film, are disposed at an interval with respect to the X-axis direction. Portions of the source electrode 24B and the drain electrode 24C are above and directly contacted with the semiconductor section 24D. Thus, the source electrode 24B and the drain electrode 24C are connected to the semiconductor section 24D. The source electrodes 24B are wide sections of the source lines 27 that extend in the Y-axis direction. Intermediate electrodes 39, which are portions of the third metal film, are disposed to overlap end portions of the drain electrodes 24C opposite from the end portions overlapping the semiconductor sections 24D, respectively. The first interlayer insulating film 35 and the planarization film 36, which are disposed between the drain electrodes 24C and the intermediate electrodes 39, include first pixel contact holes CH1 that are communicated with each other. The drain electrodes 24C are connected to the intermediate electrodes 39, respectively, via the first pixel contact holes CH1. The intermediate electrodes 39 are disposed to overlap portions of the pixel electrodes 25, which are portions of the second transparent electrode film. The second interlayer insulating film 37 and the third interlayer insulating film 38, which are disposed between the intermediate electrodes 39 and the portions of the pixel electrodes 25, include second pixel contact holes CH2 that are communicated with each other. The intermediate electrodes 39 are connected to the pixel electrodes 25, respectively, via the second pixel contact holes CH2. The common electrode 28 includes holes that overlap the second pixel contact holes CH2 so as to arrange the pixel electrodes 25 therein.

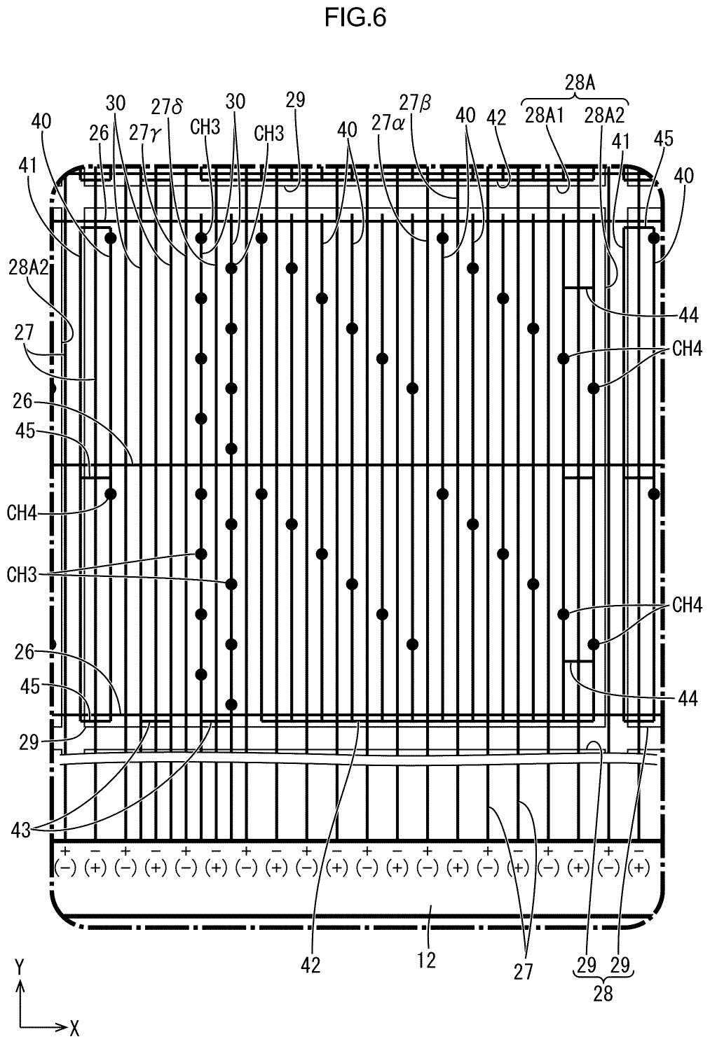

A connection structure of the touch electrodes 29 (the common electrode 28) and the touch lines 30 will be described. As illustrated in FIG. 5, the second interlayer insulating film 37 is disposed between the touch lines 30, which are portions of the third metal film, and the touch electrodes 29, which are portions of the first transparent electrode film. The second interlayer insulating film 37 includes first contact holes CH3 via which the touch lines 30 are connected to the touch electrodes 29, respectively. The first contact hole CH3 is in a portion of the second interlayer insulating film 37 overlapping the touch line 30 and the touch electrode 29 to be connected to the touch line 30. Specifically, the first contact hole CH3 overlaps a portion of the source electrode 24B and a portion of the semiconductor section 24D of a relevant TFT 24 out of the TFTs 24 that overlap the touch line 30 and the touch electrode 29. The first contact holes CH3 are provided for the touch electrode 29 and the touch line 30 that are to be connected (eight first contact holes CH3 in FIG. 6) and are away from each other in the Y-axis direction. The touch lines 30 have wide sections similar to the source lines 27. The touch lines 30 are disposed such that the wide sections overlap portions of the source electrodes 24B and the semiconductor sections 24D, and the first contact holes CH3.

As illustrated in FIG. 6, the array substrate 21 includes first connection lines 40 (second lines) that are connected to the touch electrode 29 and a second connection line 41 that is connected to at least one of the first connection lines 40. In FIG. 6, one of the touch electrodes 29 is illustrated and the gate lines 26, the source lines 27, the touch lines 30, the first connection lines 40, and the second connection line 41 that are relevant to the one of the touch electrodes 29 are illustrated. In FIG. 6, the source lines 27 that are disposed to overlap the touch lines 30 are illustrated on the left side of the respective touch lines 30.

As illustrated in FIG. 6, the first connection lines 40 extend substantially along the Y-axis direction similar to the touch lines 30. The first connection line 40 is disposed to overlap a target touch electrode 29 to be connected and extends in the Y-axis direction only within the area of the target touch electrode 29. The first connection line 40 is connected to the target touch electrode 29 at multiple portions (two portions in FIG. 6). This decreases the resistance variation in the electrical resistance distribution of the touch electrode 29. The first connection lines 40 are not connected to the driver 12. The first connection lines 40 are included in the same layer as the touch lines 30 and are disposed to overlap the source lines 27, respectively, in a plan view. In FIG. 6, the source lines 27 that are disposed to overlap the first connection lines 40 are illustrated on the left side of the respective first connection lines 40. The first connection lines 40 extend along the Y-axis direction similar to the source lines 27 and the touch lines 30. The first connection lines 40 do not cross the first dividing opening 28A1 between the target touch electrode 29 and the touch electrode 29 that is adjacent to the target touch electrode 29 in the Y-axis direction.

As illustrated in FIG. 6, the first connection lines 40 are collectively arranged in a section of the target touch electrode 29 with respect to the X-axis direction. Specifically, the first connection lines 40 are arranged in a right section of the target touch electrode 29 in FIG. 6. In FIG. 6, twelve first connection lines 40 are collectively arranged in the right section of the target touch electrode 29. The touch lines 30 are arranged in a left section of the target touch electrode 29. In FIG. 6, four touch lines 30 are collectively arranged in the left section of the target touch electrode 29. Among the four touch lines 30 illustrated in FIG. 6, the two touch lines 30 on the right side are connected to the target touch electrode 29 illustrated in FIG. 6 and the two touch lines 30 on the left side are connected to another touch electrode 29 that is not the target touch electrode 29 in FIG. 6. One of the first connection lines 40 is disposed at the left end of the target touch electrode 29 in FIG. 6 and between the touch line 30 and the second connection line 41, which will be described later.

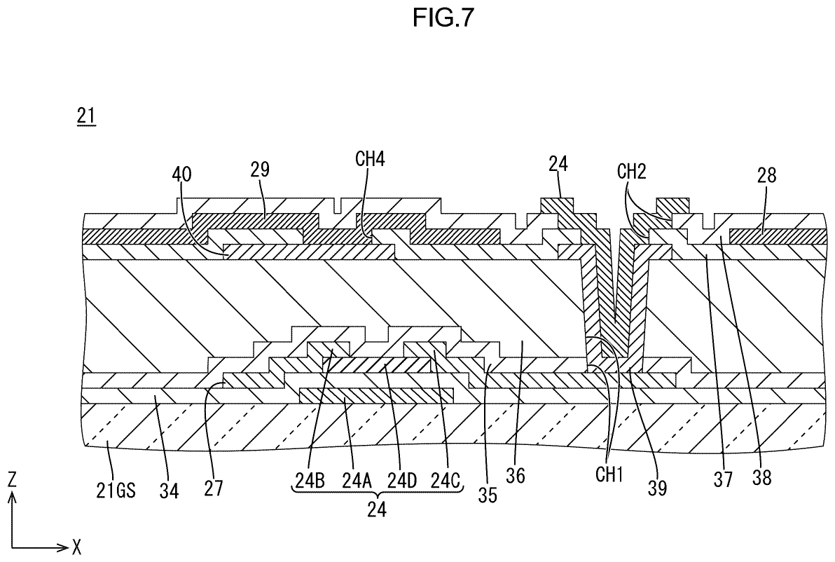

A connection structure of the touch electrode 29 and the first connection lines 40 will be described. As illustrated in FIG. 7, the first connection lines 40 are portions of the third metal film portions of which are configured as the touch lines 30. FIG. 7 illustrates a cross-sectional configuration of a portion of the array substrate 21 including the TFT 24 and the first connection line 40. The second interlayer insulating film 37 is between the first connection lines 40, which are portions of the third metal film, and the target touch electrode 29 to be connected. The second interlayer insulating film 37 includes second contact holes CH4 via which the touch electrode 29 is connected to the first connection lines 40. The second contact holes CH4 are in portions of the second interlayer insulating film 37 overlapping the respective first connection lines 40 and the target touch electrode 29. Specifically, the second contact hole CH4 overlaps a portion of the source electrode 24B and a portion of the semiconductor section 24D of a relevant TFT 24 out of the TFTs 24 that overlap the touch electrode 29 and the first connection line 40. Multiple second contact holes CH4 (two second contact holes CH4 in FIG. 6) are formed for one first connection line 40 and are arranged at an interval with respect to the Y-axis direction. The first connection lines 40 have wide sections similar to the source lines 27 and the touch lines 30. The first connection lines 40 are disposed such that the wide sections overlap portions of the source electrodes 24B and the semiconductor sections 24D, and the second contact holes CH4. The first interlayer insulating film 35 and the planarization film 36 are between the first connection lines 40, which are portions of the third metal film, and the source lines 27 overlapping the respective first connection lines 40. The first connection lines 40 and the source lines 27 are insulated from each other.

As illustrated in FIG. 6, the second connection lines 41 are disposed to overlap the second dividing openings 28A2 between the touch electrodes 29 that are adjacent to each other in the X-axis direction. Namely, the second connection line 41 does not overlap the touch electrode 29. The second connection lines 41 do not cross the first dividing opening 28A1 between the touch electrodes 29 that are adjacent to each other in the Y-axis direction. The second connection lines 41 are portions of the third metal film portions of which are configured as the touch lines 30 and the first connection lines 40. The second connection lines 41 are disposed to overlap the source lines 27, respectively, in a plan view. The source line 27 overlapping the second connection line 41 is disposed to overlap the second dividing opening 28A2. In FIG. 6, the source lines 27 that are disposed to overlap the second connection lines 41 are illustrated on the left side of the respective second connection lines 41. The second connection lines 41 extend along the Y-axis direction similar to the source lines 27, the touch lines 30, and the first connection lines 40. The second connection line 41 is connected to a relevant first connection line 40 via a fourth short-circuit line 45. Namely, the second connection line 41 is indirectly connected to the touch electrode 29 via the fourth short-circuit line 45 and the first connection line 40. The second connection line 41 extends in the Y-axis direction only within the Y-axis length of the target first connection line 40 and the area of the target touch electrode 29 to be connected.

As previously described, with the first connection lines 40 being connected to the touch electrode 29, the resistance variation in the electrical resistance distribution of the touch electrode 29 can be decreased. On the other hand, if the first connection line 40 is not correctly connected to the touch electrode 29, the connection resistance of the touch electrode 29 and the first connection line 40 is increased. With such a configuration, the electric field that is created by the source line 27 that overlaps the first connection line 40 via the first interlayer insulating film 35 and the planarization film 36 may adversely affect the TFTs 24 (other component), which are disposed near the first connection line 40, through the first connection line 40. To decrease the resistance variation in the electrical resistance distribution of the touch electrode 29, the number of connection portions (the second contact holes CH4) of the first connection line 40 and the touch electrode 29 may be increased. However, near the connection portions of the first connection lines 40 and the touch electrode 29, recesses are created on the inner surface of the array substrate 21 due to the second contact holes CH4 that extend through the first interlayer insulating film 35 and the planarization film 36. Disorder of orientation in the liquid crystal molecules included in the liquid crystal layer 22 is likely to occur due to the recesses. Therefore, it is not desirable to increase the number of connection portions of the first connection line 40 and the touch electrode 29. In this embodiment, the number of connection portions of the touch line 30 and the touch electrode 29 is greater than the number of connection portions of the first connection line 40 and the touch electrode 29 because it is quite important to ensure the supply of the common potential signals and the touch signals, which are sent via the touch line 30, to the touch electrode 29.

As illustrated in FIG. 6, the array substrate 21 according to this embodiment includes first short-circuit lines 42 (third lines) that connect the first connection lines 40 to create a short circuit. The first short-circuit lines 42 extend in the X-axis direction (a second direction) that crosses the extending direction (the Y-axis direction) in which the first connection lines 40 extend. The first short-circuit line 42 is disposed to overlap in a plan view the target touch electrode 29 that is to be connected to the target first connection lines 40 that are to be short circuited. The first short-circuit line 42 is disposed in a right section of the target touch electrode 29 that is to be connected to the target first connection lines 40 to be short circuited. Namely, the first short-circuit line 42 is disposed in an area where the target first connection lines 40 to be short circuited is arranged. The first short-circuit line 42 is connected to all the first connection lines 40 (the twelve first connection lines 40) that are arranged in the right section of the touch electrode 29 in FIG. 6. Therefore, the first connection lines 40 that are arranged in the right section of the touch electrode 29 in FIG. 6 are short circuited by one first short-circuit line 42. The first short-circuit line 42 is connected to lower ends of the first connection lines 40 in FIG. 6. Namely, the first short-circuit line 42 is arranged near the lower edge of the touch electrode 29 in FIG. 6. The first short-circuit line 42 is disposed to overlap the gate line 26 in a plan view. In FIG. 6, the first short-circuit line 42 overlapping the gate line 26 is illustrated below the gate line 26. In FIG. 6, among the gate lines 26, three gate lines 26 overlapping the first short-circuit line 42 and a second short-circuit line 43, the third short-circuit line 44, and the fourth short-circuit line 45 are illustrated. The first short-circuit lines 42 are not connected to the driver 12.

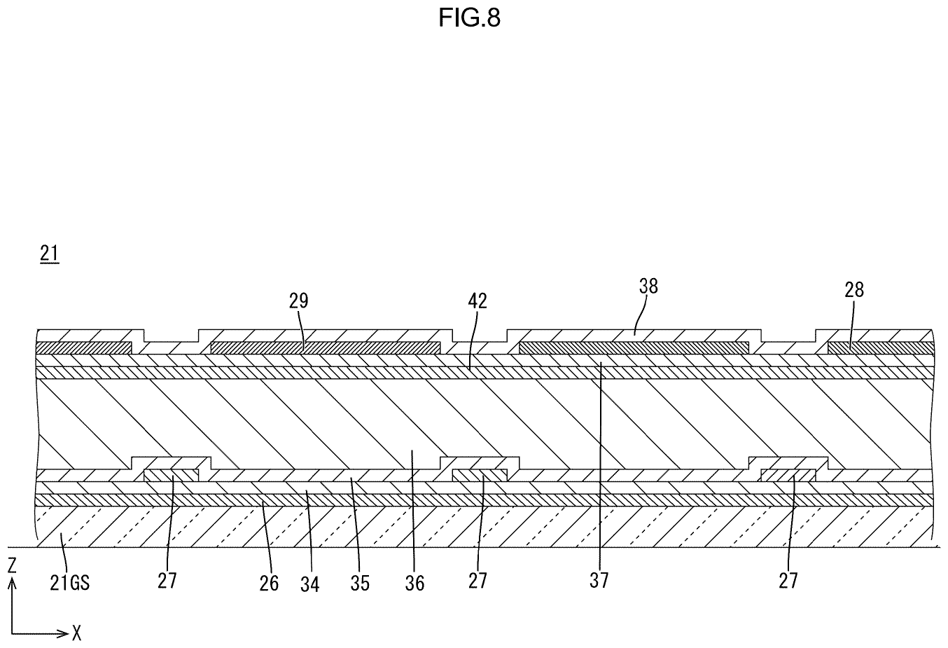

As illustrated in FIG. 8, the first short-circuit lines 42 are portions of the third metal film portions of which are configured as the touch lines 30 and the first connection lines 40. The first short-circuit line 42 is directly continuous to and connected to the target first connection lines 40. FIG. 8 illustrates a cross-sectional configuration of the portion of the array substrate 21 including the first short-circuit line 42 and the gate line 26 taken along the X-axis direction. The gate insulating film 34, the first interlayer insulating film 35, and the planarization film 36 are between the first short-circuit lines 42, which are portions of the third metal film, and the gate lines 26 overlapping the first short-circuit lines 42. Thus, the first short-circuit lines 42 and the gate lines 26 are insulated from each other. The first interlayer insulating film 35 and the planarization film 36 are between the first short-circuit lines 42, which are portions of the third metal film, and the source lines 27, which cross the first short-circuit lines 42. Thus, the first short-circuit lines 42 and the source lines 27 are insulated from each other. The third interlayer insulating film 38 is between the first short-circuit lines 42, which are portions of the third metal film, and the touch electrodes 29 overlapping the first short-circuit lines 42. Thus, the first short-circuit lines 42 and the touch electrodes 29 are insulated from each other.

Among the source lines 27 overlapping the first connection lines 40, respectively, illustrated in FIG. 6, two source lines that are adjacent to each other at an interval (an interval of the width dimension of the pixel electrode 25) in the X-axis direction are defined as a first source line 27α and a second source line 27β (second line overlapping first lines, one of the first lines, another one of the first lines). As illustrated in FIG. 6, the first source line 27α is one of the two source lines 27 that are adjacent to each other at an interval with respect to the X-axis direction. The second source line 27β is another one of the two source lines 27 that is adjacent to the one source line 27 with respect to the X-axis direction. The driver 12 supplies a first image signal (a first signal) to the first source line 27α out of the first source line 27α and the second source line 27β and supplies a second image signal (a second signal) to the second source line 27B. The second image signal has a polarity that is opposite from a polarity of the first image signal. The polarity of the image signal supplied to each of the source lines 27 is described below each source line 27 in FIG. 6 with the symbol of “+” or “−”. Specifically, with the polarity of the first image signal supplied to the first source line 27α being “+”, the polarity of the second image signal supplied to the second source line 27β is “−”. On the other hand, with the polarity of the first image signal supplied to the first source line 27α being “−”, the polarity of the second image signal supplied to the second source line 27β is “+”. Among the source lines 27 arranged in the X-axis direction, the driver 12 periodically switches the polarity of the image signals to be supplied to the odd-numbered source lines 27 from one end in the X-axis direction and the polarity of the image signals to be supplied to the even-numbered source lines 27 from one end in the X-axis direction between a positive polarity and a negative polarity.

With the first connection lines 40 arranged in the right section of the touch electrode 29 in FIG. 6 being short-circuited by the first short-circuit line 42 in this embodiment, the connection resistance of the first connection liens 40 and the touch electrode 29 is reduced. Furthermore, the first image signal and the second image signal having opposite polarities are respectively supplied by the driver 12 to the two source lines 27α, 27β that overlap the two first connection lines 40 via the first interlayer insulating film 35 and the planarization film 36. Therefore, an electric field that is created by the first source line 27α being supplied with the first image signal and affects the overlapping first connection line 40 and an electric field that is created by the second source line 27β being supplied with the second image signal and affects the overlapping first connection line 40 are cancelled each other. With the electric fields that affect the two first connection lines 40 overlapping the two source lines 27α, 27β being cancelled each other, difference is less likely to be caused in the electric fields of the back channels that may be created in the respective semiconductor sections 24D of the two TFTs 24 overlapping the two first connection lines 40. Accordingly, the transistor characteristics of the two TFTs 24 are less likely to change as time passes and the display quality is less likely to be lowered due to the change of the transistor characteristics.

As illustrated in FIG. 6, the array substrate 21 includes second short-circuit lines 43 (fifth lines) each of which short circuits the two touch lines 30 that are adjacent to each other in the X-axis direction at an interval (an interval of the width dimension of one pixel electrode 25). The second short-circuit lines 43 extend in the X-axis direction that crosses the extending direction (the Y-axis direction) in which the touch lines 30 extend. The second short-circuit line 43 is connected to the two touch lines 30 that are connected to the same touch electrode 29. The second short-circuit line 43 is disposed to overlap in a plan view the target touch electrode 29 that is to be connected to the target touch lines 30 that are to be short circuited. The second short-circuit lines 43 are disposed in a left section of the target touch electrode 29 that is to be connected to the target touch lines 30 to be short circuited. Namely, the second short-circuit lines 43 are disposed in an area where the target touch lines 30 to be short circuited are arranged. The two second short-circuit lines 43 are disposed such that each of the two second short-circuit lines 43 is connected to every two of the four touch lines 30 that are arranged in the left section of the touch electrode 29 in FIG. 6. The second short-circuit line 43 is disposed to overlap the gate line 26 in a plan view. In FIG. 6, the second short-circuit line 43 overlapping the gate line 26 is illustrated below the gate line 26. The second short-circuit line 43 is indirectly connected to the driver 12 via the touch lines 30.

As illustrated in FIG. 8, the second short-circuit lines 43 are portions of the third metal film portions of which are configured as the touch lines 30, the first connection lines 40, and the first short-circuit lines 42. The second short-circuit line 43 is directly continuous to and connected to the target touch lines 30. Namely, the relation of the second short-circuit line 43 and the touch lines 30 is similar to the relation of the first short-circuit line 42 and the first connection lines 40. The relation of the second short-circuit line 43 and the gate line 26, the source line 27, and the touch electrode 29 is similar to the relation of the first short-circuit line 42 and the gate line 26, the source line 27, and the touch electrode 29. The gate insulating film 34, the first interlayer insulating film 35, and the planarization film 36 are between the second short-circuit lines 43, which are portions of the third metal film, and the gate lines 26 overlapping the second short-circuit lines 43. Thus, the second short-circuit lines 43 and the gate lines 26 are insulated from each other. The first interlayer insulating film 35 and the planarization film 36 are between the second short-circuit lines 43, which are portions of the third metal film, and the source lines 27, which cross the second short-circuit lines 43. Thus, the second short-circuit lines 43 and the source lines 27 are insulated from each other. The third interlayer insulating film 38 is between the second short-circuit lines 43, which are portions of the third metal film, and the touch electrodes 29 overlapping the second short-circuit lines 43. Thus, the second short-circuit lines 43 and the touch electrodes 29 are insulated from each other.

Among the source lines 27 overlapping the touch lines 30, respectively, illustrated in FIG. 6, two source lines 27 overlapping the two touch lines 30 that are connected to the same touch electrode 29 and connected to the same second short-circuit line 43 are defined as a third source line 27γ (one first line) and a fourth source line 27δ (fourth line overlapping first lines, one of the first lines, another one of the first lines). As illustrated in FIG. 6, the third source line 27γ and the fourth source line 27δ are adjacent to each other at an interval (an interval of a width dimension of one pixel electrode 25) with respect to the X-axis direction. The third source line 27γ is one of the two source lines 27 that are adjacent to each other at an interval with respect to the X-axis direction. The fourth source line 27δ is another one of the two source lines 27 that are adjacent to each other at an interval with respect to the X-axis direction. The driver 12 supplies a third image signal (a third signal) to the third source line 27γ out of the two source lines 27γ, 27δ and supplies a fourth image signal (a fourth signal) to the fourth source line 27δ. Specifically, with the polarity of the third image signal supplied to the third source line 27γ being “+”, the polarity of the fourth image signal supplied to the fourth source line 27δ is “−”. On the other hand, with the polarity of the third image signal supplied to the third source line 27γ being “−”, the polarity of the fourth image signal supplied to the fourth source line 27δ is “+”.

With the two touch lines 30 being short-circuited by the second short-circuit line 43 in this embodiment, the connection resistance of the two touch lines 30 and the touch electrode 29 is reduced. Furthermore, the third image signal and the fourth image signal having opposite polarities are respectively supplied by the driver 12 to the two source lines 27γ, 27δ that overlap the two touch lines 30 via the first interlayer insulating film 35 and the planarization film 36. Therefore, an electric field that is created by the third source line 27γ being supplied with the third image signal and affects the overlapping touch line 30 and an electric field that is created by the fourth source line 27δ being supplied with the fourth image signal and affects the overlapping touch line 30 are cancelled each other. With the electric fields that affect the two touch lines 30 overlapping the two source lines 27γ, 27δ being cancelled each other, difference is less likely to be caused in the electric fields of the back channels that may be created in the respective semiconductor sections 24D of the two TFTs 24 overlapping the two touch lines 30. Accordingly, the transistor characteristics of the two TFTs 24 are less likely to change as time passes and the display quality is less likely to be lowered due to the change of the transistor characteristics. Thus, the electric fields that are created by the source lines 27α-27δ overlapping the first connection lines 40 and the touch lines 30, respectively, are less likely to change the transistor characteristics of the TFTs 24 via the first connection lines 40 and the touch lines 30.

As illustrated in FIG. 6, the array substrate 21 includes third short-circuit lines 44 each of which short circuits predefined two first connection lines 40. Specifically, the third short-circuit lines 44 are connected to the two first connection lines 40 out of the first connection lines 40 that are connected to the target touch electrode 29 and the two first connection lines 40 are arranged in a right end section of the target touch electrode 29 in FIG. 6. The third short-circuit lines 44 extend in the X-axis direction. Three third short-circuit lines 44 are arranged at intervals with respect to the Y-axis direction as illustrated in FIG. 6. The third short-circuit line 44 is disposed to overlap the gate line 26 in a plan view. The third short-circuit lines 44 are not connected to the driver 12. The third short-circuit lines 44 are portions of the third metal film portions of which are configured as the touch lines 30, the first connection lines 40, the first short-circuit lines 42, and the second short-circuit lines 43 (refer to FIG. 8). The third short-circuit lines 44 are directly continuous to and connected to the target first connection line 40. The relation of the third short-circuit lines 44 and the first connection lines 40 is similar to the relation of the first short-circuit line 42 and the first connection lines 40. The relation of the third short-circuit lines 44 and the gate line 26, the source line 27, and the touch electrode 29 is similar to the relation of the first short-circuit line 42 and the gate line 26, the source line 27, and the touch electrode 29.

As illustrated in FIG. 6, the array substrate 21 includes fourth short-circuit lines 45 that short circuit a predefined first connection line 40 and the second connection line 41. Specifically, the fourth short-circuit lines 45 are connected to a target first connection line 40 out of the first connection lines 40 that are connected to the target touch electrode 29 and the second connection line 41 that is adjacent to the target first connection line 40 with respect to the X-axis direction. The target first connection line 40 is arranged in a left end section of the target touch electrode 29 in FIG. 6. The fourth short-circuit lines 45 extend in the X-axis direction. Three fourth short-circuit lines 45 are arranged at intervals with respect to the Y-axis direction as illustrated in FIG. 6. The fourth short-circuit line 45 is disposed to overlap the gate line 26 in a plan view. The fourth short-circuit lines 45 are not connected to the driver 12. The fourth short-circuit lines 45 are portions of the third metal film portions of which are configured as the touch lines 30, the first connection lines 40, the first short-circuit lines 42, the second short-circuit lines 43, and the third short-circuit lines 44 (refer to FIG. 8). The fourth short-circuit lines 45 are directly continuous to and connected to the target first connection line 40 and the second connection line 41. The relation of the fourth short-circuit lines 45 and the first connection line 40 and the second connection line 41 is similar to the relation of the first short-circuit line 42 and the first connection lines 40. The relation of the fourth short-circuit lines 45 and the gate line 26, the source line 27, and the touch electrode 29 is similar to the relation of the first short-circuit line 42 and the gate line 26, the source line 27, and the touch electrode 29.

As previously described, the array substrate 21 (a wiring board) of this embodiment includes source lines 27 (first lines) extending along a first direction, first connection lines 40 (second lines) extending along the first direction, a touch electrode 29 (a first electrode) connected to the first connection lines 40, a first short-circuit line 42 (a third line) extending along a second direction that crosses the first direction, and a driver 12 (the signal supply section) that is connected to the source lines 27 and is not connected to the first connection lines 40 and the first short-circuit line 42. The source lines 27 includes at least two source lines 27 (the second line overlapping first lines) that are arranged at an interval in the second direction. The first connection lines 40 include at least two first connection lines 40 that are arranged at an interval in the second direction and overlap the at least two source lines 27, respectively, via the first interlayer insulating film 35 and the planarization film 36, which are insulating films. The driver 12 is configured to supply the first image signal (the first signal) to the first source line 27α, which is one source line 27 out of the at least two source lines 27, and supply the second image signal (the second signal) having an opposite polarity from the polarity of the first image signal to the second source line 27B, which is another source line 27 out of the at least two source lines 27. The first short-circuit line 42 is connected to the at least two first connection lines 40.

With the at least two first connection lines 40 being connected to the touch electrode 29, the resistance variation in the electrical resistance distribution of the touch electrode 29 can be decreased. On the other hand, if the first connection line 40 is not correctly connected to the touch electrode 29, the connection resistance of the touch electrode 29 and the first connection line 40 is increased. Therefore, the electric field that is created by the source line 27 that overlaps the first connection line 40 via the first interlayer insulating film 35 and the planarization film 36 may adversely affect other components, which are disposed near the first connection line 40, through the first connection line 40.

With the at least two first connection lines 40 being short-circuited by the first short-circuit line 42 that extends along the second direction, the connection resistance of the at least two first connection liens 40 and the touch electrode 29 is reduced. Furthermore, the first image signal and the second image signal having opposite polarities are supplied by the driver 12 to the two source lines 27 that overlap the at least two first connection lines 40, respectively, via the first interlayer insulating film 35 and the planarization film 36, which are the insulating films. Therefore, an electric field that is created by the first source line 27α (the one source line 27) being supplied with the first image signal and affects the overlapping first connection line 40 and an electric field that is created by the second source line 27β (the other source line 27) being supplied with the second image signal and affects the overlapping first connection line 40 are cancelled each other. Accordingly, the electric field that is created by the source line 27 is less likely to adversely affect other components, which are disposed near the first connection line 40, through the first connection line 40.

The array substrate 21 further includes the touch lines 30 (the fourth lines) that extend along the first direction and are connected to the touch electrode 29, and the second short-circuit line 43 (the fifth line) extending along the second direction. The touch lines 30 includes at least two touch lines 30 that are arranged at an interval with respect to the second direction. The source lines 27 include another at least two source lines 27 (the fourth line overlapping first lines) that are arranged at an interval with respect to the second direction and overlap the at least two touch lines 30, respectively, via the first interlayer insulating film 35 and the planarization film 36, which are the insulating films. The driver 12 is configured to supply the common potential signals and the touch signals, which are the third signals, to the at least two touch lines 30, supply the third image signal (the fourth signal) to the third source line 27γ, which is one of the other at least two source lines 27 overlapping the at least two touch lines 30, and supply the fourth image signal (the fifth signal) to the fourth source line 27δ, which is another one of the other at least two source lines 27 overlapping the at least two touch lines 30. The fourth image signal has an opposite polarity from the polarity of the third image signal. The second short-circuit line 43 is connected to the at least two touch lines 30. The common potential signals and the touch signals, which are the third signals, output from the driver 12 are supplied to the touch electrode 29 via the at least two touch lines 30. With the at least two touch lines 30 being connected by the second short-circuit line 43 extending along the second direction, the connection resistance of the at least two touch lines 30 and the touch electrode 29 is reduced. Furthermore, the third image signal and the fourth image signal having opposite polarities are supplied by the driver 12 to the other at least two source lines 27 that overlap the at least two touch lines 30, respectively, via the first interlayer insulating film 35 and the planarization film 36, which are the insulating films. Therefore, an electric field that is created by the third source line 27γ (the one source line 27) being supplied with the third image signal and affects the overlapping touch line 30 and an electric field that is created by the fourth source line 27δ (the other source line 27) being supplied with the fourth image signal and affects the overlapping touch line 30 are cancelled each other. Accordingly, the electric field that is created by the source line 27 is less likely to adversely affect other components, which are disposed near the touch line 30, through the touch line 30. Thus, adverse influence by the electric field that is created by the source lines 27 overlapping the first connection lines 40 and the touch lines 30 is less likely to be caused.

The array substrate 21 further includes the pixel electrodes 25 (the second electrodes) and the TFTs 24 (the switching components) that are connected to the source lines 27 and the pixel electrodes 25, respectively. The first connection line 40 is disposed such that a portion of the first connection line 40 overlaps at least a portion of the TFT 24 via the first interlayer insulating film 35 and the planarization film 36. The first image signal output from the driver 12 is supplied to the target pixel electrode 25 via the first source line 27α, which is one of the at least two source lines 27, and the TFT 24 that is connected to the first source line 27α, which is one of the at least two source lines 27. The second image signal output from the driver 12 is supplied to the target pixel electrode 25 via the second source line 27β, which is the other one of the at least two source lines 27, and the TFT 24 that is connected to the second source line 27β, which is the other one of the at least two source lines 27. With the at least two first connection lines 40 being connected to the first short-circuit line 42, the electric field that is created by the source line 27 is less likely to adversely affect the TFT 24, which overlaps the first connection line 40, via the first connection line 40.

The liquid crystal panel 11 (a display device) according to this embodiment includes the array substrate 21 and the opposed substrate 20 that is disposed to be opposite and away from the array substrate 21. According to the liquid crystal panel 11 having such a configuration, display quality is less likely to be lowered due to the electric field created by the source line 27.

### Second Embodiment

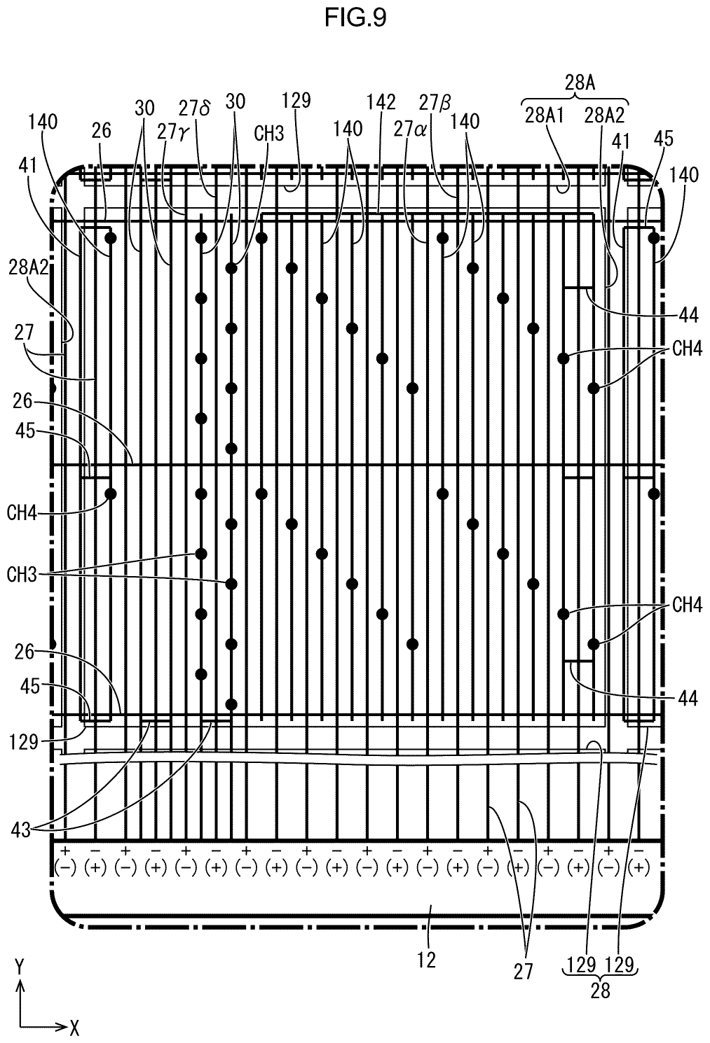

A second embodiment will be described with reference to FIG. 9. The second embodiment includes first short-circuit lines 142 having a configuration different from the configuration of the first embodiment. Configuration, operations, and effects similar to those of the first embodiment may not be described.

As illustrated in FIG. 9, the first short-circuit line 142 of this embodiment is disposed to be connected to upper ends of all of first connection lines 140 arranged in a right section of a touch electrode 129 in FIG. 9. Namely, the first short-circuit line 142 is arranged near an upper edge of the touch electrode 129 in FIG. 9.

### Third Embodiment

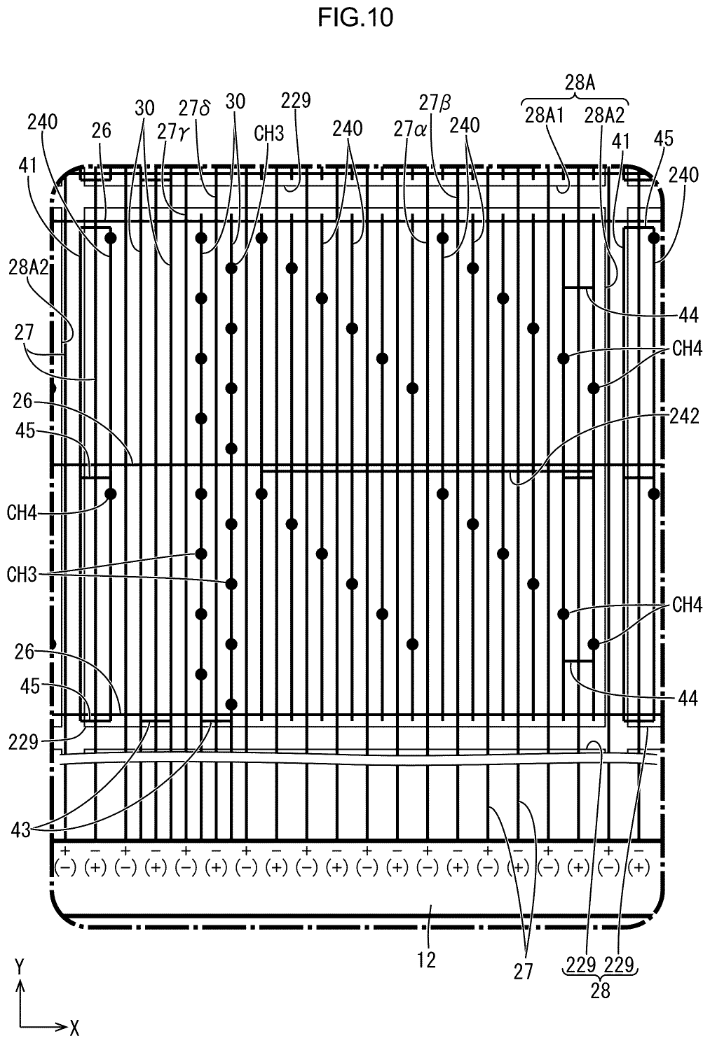

A third embodiment will be described with reference to FIG. 10. The third embodiment includes first short-circuit lines 242 having a configuration different from the configuration of the first embodiment. Configuration, operations, and effects similar to those of the first embodiment may not be described.

As illustrated in FIG. 10, the first short-circuit line 242 is disposed to be connected to middle portions of all of first connection lines 240 arranged in a right section of a touch electrode 229 in FIG. 10. Namely, the first short-circuit line 242 is arranged in a middle of the touch electrode 229 with respect to an upper-bottom direction in FIG. 10.

### Fourth Embodiment

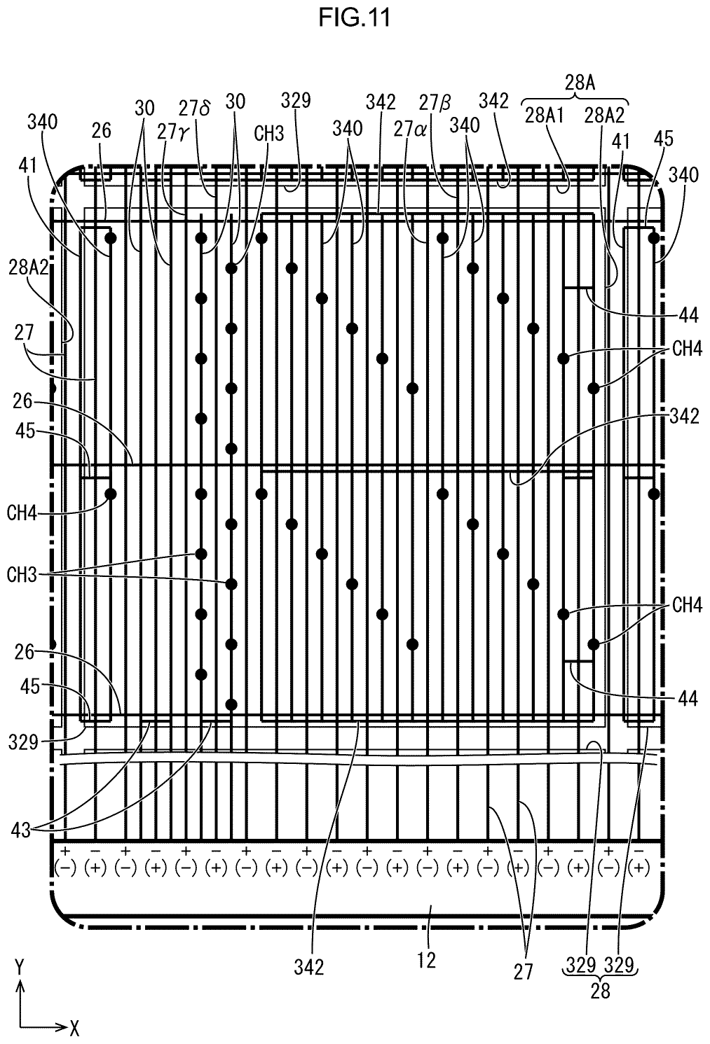

A fourth embodiment will be described with reference to FIG. 11. The fourth embodiment includes first short-circuit lines 342 having a configuration different from the configuration of the first embodiment. Configuration, operations, and effects similar to those of the first embodiment may not be described.

As illustrated in FIG. 11, three first short-circuit lines 342 are arranged at intervals with respect to the Y-axis direction. Specifically, a first one of the three first short-circuit lines 342 is connected to lower ends of the first connection lines 340 in FIG. 11, a second one of the three first short-circuit lines 342 is connected to upper ends of the first connection lines 340 in FIG. 11, and a third one of the three first short-circuit lines 342 is connected to middle portions of the first connection lines 340 in FIG. 11 with respect to the upper-bottom direction. The first short-circuit lines 342 are connected to all of the first connection lines 340 that are arranged in a right section of a touch electrode 329 in FIG. 11. With the first connection lines 340 being connected to the first short-circuit lines 342, the connection resistance of each of the first connection lines 340 and the touch electrode 329 is further reduced.

As previously described, according to this embodiment, the first short-circuit lines 342 are arranged at intervals with respect to the first direction and are connected to at least two first connection lines 340. With the at least two first connection lines 340 being connected to the first short-circuit lines 342, the connection resistance of the at least two first connection lines 340 and the touch electrode 329 is further reduced.

### Fifth Embodiment

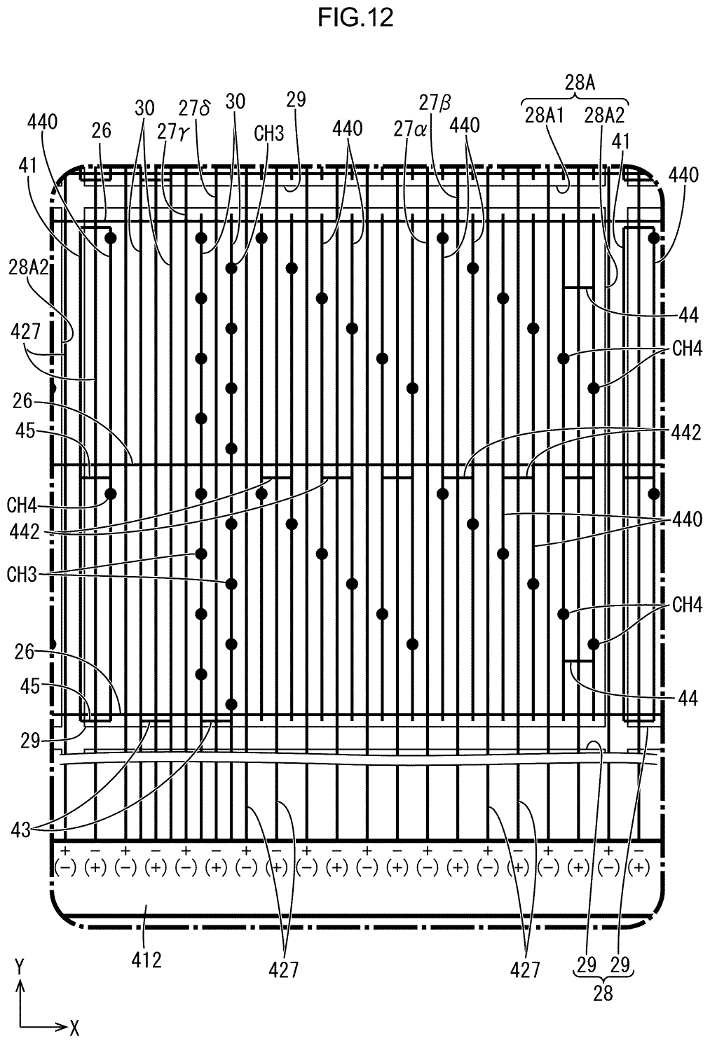

A fifth embodiment will be described with reference to FIG. 12. The fifth embodiment includes first short-circuit lines 442 having a configuration different from the configuration of the first embodiment. Configuration, operations, and effects similar to those of the first embodiment may not be described.

As illustrated in FIG. 12, the first short-circuit lines 442 are arranged at intervals with respect to the X-axis direction. Each of the first short-circuit lines 442 is connected to every two first connection lines 440. The length dimension of the first short-circuit lines 442 measured in the X-axis direction is substantially same as an interval between the two first connection lines 440 (source lines 427) that are adjacent to each other with respect to the X-axis direction and substantially same as a width dimension of the pixel electrode 25 (refer to FIG. 4). The interval between the two first short-circuit lines 442 that are adjacent to each other with respect to the X-axis direction is substantially same as the width dimension of the pixel electrode 25. The two source lines 427 overlapping the two first connection lines 440 that are short circuited by the first short-circuit line 442 are supplied with image signals having opposite polarities from the driver 12. Therefore, in this embodiment, the electric fields that are created by the source lines 427 and affect the overlapping first connection lines 440 are cancelled each other similar to the first embodiment. The first-short circuit lines 442 are connected to middle portions of the first connection lines 440 with respect to the upper-bottom direction in FIG. 12.

### Other Embodiments

The technology described herein is not limited to the embodiments described above and illustrated by the drawings. For example, the following embodiments will be included in the technical scope of the present technology.

(1) The connection portions of the first connection lines 40, 140, 240, 340, 440 and the first short-circuit lines 42, 142, 242, 342, 442 with respect to the Y-axis direction may be altered as appropriate from those illustrated in the drawings.

(2) In the configuration of the fourth embodiment, the number of the first short-circuit lines 342 may be two or four or more.

(3) The number of the first connection lines 40, 140, 240, 340, 440 that are short-circuited by the first short-circuit lines 42, 142, 242, 342, 442 may be altered as appropriate from those illustrated in the drawings.

(4) The number of the touch lines 30 that are short circuited by the second short-circuit line 43 may be altered as appropriate from those illustrated in the drawings.

(5) The number of the third short-circuit lines 44 and the fourth short-circuit lines 45 may be altered as appropriate from those illustrated in the drawings.

(6) The third short-circuit lines 44 may not be included.

(7) The fourth short-circuit lines 45 may not be included. In such a configuration, the second connection line 41 may be connected to the touch electrode 29, 129, 229, 329.

(8) The short-circuit lines 42-45, 142, 242, 342, 442 may not overlap the gate lines 26.

(9) The number of connection portions of the touch lines 30 and the touch electrodes 29, 129, 229, 329 may be altered as appropriate from that illustrated in the drawings.

(10) The number of connection portions of the first connection lines 40, 140, 240, 340, 440 and the touch electrodes 29, 129, 229, 329 may be altered as appropriate from that illustrated in the drawings.

(11) The source lines 27, 427, the touch lines 30, and the first connection lines 40, 140, 240, 340, 440 may not include the wide sections.

(12) The overlapping portions of the TFTs 24 and the touch lines 30 may be altered as appropriate from those illustrated in the drawings. Similarly, the overlapping portions of the TFTs 24 and the first connection lines 40, 140, 240, 340, 440 may be altered as appropriate from those illustrated in the drawings.

(13) The intermediate electrodes 39 that are disposed between the drain electrodes 24C of the TFTs 24 and the pixel electrodes 25 may not be included.

(14) The circuits 14 may not be included. In such a configuration, the array substrate 21 may include a gate driver that has a same function as the circuit 14. The circuit 14 may be arranged on only one edge portion of the array substrate 21.

(15) The material of the semiconductor film of the semiconductor section 24D may be polysilicon (LTPS) and amorphous silicon.

(16) The TFTs 24 may not be the bottom-gate type transistors but may be top-gate type transistors and double gate type transistors.

(17) Between the pixel electrodes 25 and the common electrode 28, the common electrode 28 may be an upper electrode that is disposed in a layer above the layer including the pixel electrodes 25 and the pixel electrodes 25 may be lower electrodes that are disposed in a layer below the layer including the pixel electrodes 25. In such a configuration, the common electrode 28, which is the upper electrode, includes slits.

(18) The touch panel pattern may use a mutual-capacitance method other than the self-capacitance method.

(19) The liquid crystal panel 11 may not include a touch panel pattern (a touch panel function). In such a configuration, the common electrode 28 (the first electrode) is not divided into pieces and the touch electrodes 29, 129, 229, 329 are not formed. Instead of the touch lines 30, a portion of the third metal film is configured as a common line (the third line) that is connected to the common electrode 28 to supply the common potential signal (the third signal).

(20) The array substrate 21 may include the color filters 31. Namely, the liquid crystal panel 11 may have a color filter on array (COA) structure.

(21) The number of colors of the color filters 31 may be four or more. A yellow color filter that exhibits yellow or a transparent color filter through which light in all wavelength regions can pass may be additionally included.

(22) The display mode of the liquid crystal panel 11 may not be the FFS mode but may be the VA mode and the IPS mode.

(23) The liquid crystal panel 11 may be a reflective liquid crystal panel or a semitransmissive liquid crystal panel other than the transmissive liquid crystal panel. With the liquid crystal panel 11 being a reflective liquid crystal type, the backlight may not be included.

(24) Display panels other than the liquid crystal panel 11 (such as organic electro luminescence display panels) may be used.

1. A wiring board comprising:
first lines extending along a first direction;
second lines extending along the first direction;
a first electrode connected to the second lines;
a third line extending along a second direction that crosses the first direction; and
a signal supply section that is connected to the first lines and is not connected to the second lines and the third line, wherein
the second lines include at least two second lines that are arranged at an interval in the second direction,
the first lines include at least two first lines that are arranged at an interval in the second direction and overlap the at least two second lines, respectively, via an insulating film, and are defined as second line overlapping first lines,
the signal supply section is configured to supply a first signal to one of the second line overlapping first lines and supply a second signal having an opposite polarity from a polarity of the first signal to another one of the second line overlapping first lines, and
the third line is connected to the at least two second lines.

2. The wiring board according to claim 1, further comprising:
fourth lines that extend along the first direction and are connected to the first electrode; and
a fifth line extending along the second direction, wherein
the fourth lines include at least two fourth lines that are arranged at an interval with respect to the second direction, the first lines include another at least two first lines that are arranged at an interval with respect to the second direction and overlap the at least two fourth lines, respectively, via the insulating film and are defined as fourth line overlapping first lines,
the signal supply section is configured to supply a third signal to the at least two fourth lines, supply a fourth signal to one of the fourth line overlapping first lines, and supply a fifth signal to another one of the fourth line overlapping first lines, the fifth signal has an opposite polarity from a polarity of the fourth signal, and
the fifth line is connected to the at least two fourth lines.

3. The wiring board according to claim 1, further comprising:
second electrodes; and
switching components connected to the first lines and the second electrodes, respectively, wherein
the second lines are disposed such that portions of the second lines overlap at least portions of the switching components, respectively, via the insulating film.

4. The wiring board according to claim 1, wherein
the third line includes at least two third lines that are arranged at an interval with respect to the first direction, and
the at least two third lines are connected to the at least two second lines.

5. A display device comprising:
the wiring board according to claim 1; and
an opposed substrate opposed to the wiring board with a gap.
